(19) United States
(12) Patent Application Publication
(10) Pub. No.: US 2017/0363722 A1
(43) Pub. Date: Dec. 21, 2017

(54) PHOTO DETECTOR, PHOTO DETECTION DEVICE, AND LIDAR DEVICE

(71) Applicant: KABUSHIKI KAISHA TOSHIBA, Tokyo (JP)

(72) Inventors: Toshiya YONEHARA, Kawasaki (JP); Kazuhiro SUZUKI, Tokyo (JP); Rei HASEGAWA, Yokohama (JP)

(73) Assignee: KABUSHIKI KAISHA TOSHIBA, Tokyo (JP)

(21) Appl. No.: 15/451,640

(22) Filed: Mar. 7, 2017

(30) Foreign Application Priority Data
Jun. 16, 2016 (JP) 2016-119865

(51) Int. Cl. G01S 7/481; H01L 31/0232; G01S 17/08; H01L 27/144; H01L 31/16; H01L 31/107

(52) U.S. Cl. CPC G01S 7/4816; H01L 31/165; H01L 31/107; G01S 17/08; H01L 27/1446; H01L 27/1443; H01L 31/02327

(57) ABSTRACT

In one embodiment, a photo detector is provided with a semiconductor layer having a first light receiving surface and a second light receiving surface opposite to the first light receiving surface, and a diffraction grating which is provided on the first light, receiving surface side of the semiconductor layer and has convex portions. The convex portions are arranged in one direction at a predetermined cycle.

### CROSS-REFERENCE TO RELATED APPLICATION

This application is based upon and claims the benefit of priority from the prior Japanese Patent Application No. 2016-119865, filed on Jun. 16, 2016, the entire contents of which are incorporated herein by reference.

### FIELD

Embodiments described herein relate generally to a photo detector, a photo detection device, and a LIDAR (Laser Imaging Detection and Ranging) device.

### BACKGROUND

A photo detector using an avalanche photo diode (APD) detects weak light, and amplifies a signal to be outputted. When an APD is made of silicon (Si), light sensitivity characteristic of the photo detector largely depends on absorption characteristic of silicon. The APD made of silicon most absorbs light with a wavelength of 400-600 nm. The APD hardly has sensitivity to light of a near infra-red wavelength band. In order to improve the sensitivity of a photo detector using silicon, a device is known in which a depletion layer is made very thick, such as several ten μm, to have sensitivity to light of a near infra-red wavelength band. However, a drive voltage of the photo detector might, become very high, such as several hundred volts.

Accordingly, in a photo detector using silicon, a structure to confine light inside the photo detector has been considered, in order to enhance detection efficiency of light of a near infra-red wavelength band.

### BRIEF DESCRIPTION OF THE DRAWINGS

FIG. 1A is a diagram showing a photo detector of a first embodiment.

FIG. 1B is a GG′ sectional view of the photo detector of the first embodiment.

FIG. 1C is an SS′ sectional view of the photo detector of the first embodiment.

FIG. 2A is a diagram showing the photo detector of the first embodiment.

FIG. 2B is a circuit diagram of the photo detector of the first embodiment.

FIG. 2C is a DD′ sectional view of the photo detector of the first embodiment.

FIG. 3A is a diagram showing a modification of the first embodiment.

FIG. 3B is a GG′ sectional view of the modification of the first embodiment,

FIG. 3C is an SS′ sectional view of the modification of the first embodiment.

FIG. 4A is a diagram shewing a photo detector of a second embodiment.

FIG. 4B is a diagram showing a photo detector of the second embodiment.

FIG. 4C is a diagram showing characteristics of the photo detector of the second embodiment.

FIG. 4D is a diagram showing characteristics of the photo detector of the second embodiment.

FIG. 5A is a diagram showing a photo detector of a third embodiment.

FIG. 5B is a diagram showing characteristics of the photo detector of the third embodiment.

FIG. 6A is a diagram showing a photo detector of a fourth embodiment.

FIG. 6B is a diagram showing characteristics of the photo detector of the fourth embodiment.

FIG. 7 is a diagram showing a photo detector of a fifth embodiment.

FIG. 8A is a diagram showing a photo detector of a sixth embodiment.

FIG. 8B is a GG′ sectional view of the photo detector of the sixth embodiment.

FIG. 8C is an SS′ sectional view of the photo detector of the sixth embodiment.

FIG. 9A is a diagram showing a photo detector of a seventh embodiment.

FIG. 9B is a GG′ sectional view of the photo detector of the seventh embodiment.

FIG. 9C is an SS′ sectional view of the photo detector of the seventh embodiment.

FIG. 10A is a diagram showing photo detectors of the seventh embodiment.

FIG. 10B is a diagram showing characteristics of the photo detectors of the seventh embodiment.

FIG. 11A is a diagram showing a photo detector of an eighth seventh embodiment.

FIG. 11B is a GG′ sectional view of the photo detector of the eighth embodiment.

FIG. 11C is an SS′ sectional view of the photo detector of the eighth embodiment.

FIG. 12A is a diagram showing a photo detection device of a ninth seventh embodiment.

FIG. 12B is a diagram showing a photo detection device of the ninth embodiment.

FIG. 12C is a diagram showing a photo detection device of the ninth embodiment.

FIG. 13 is a diagram showing a photo detection device of a tenth embodiment.

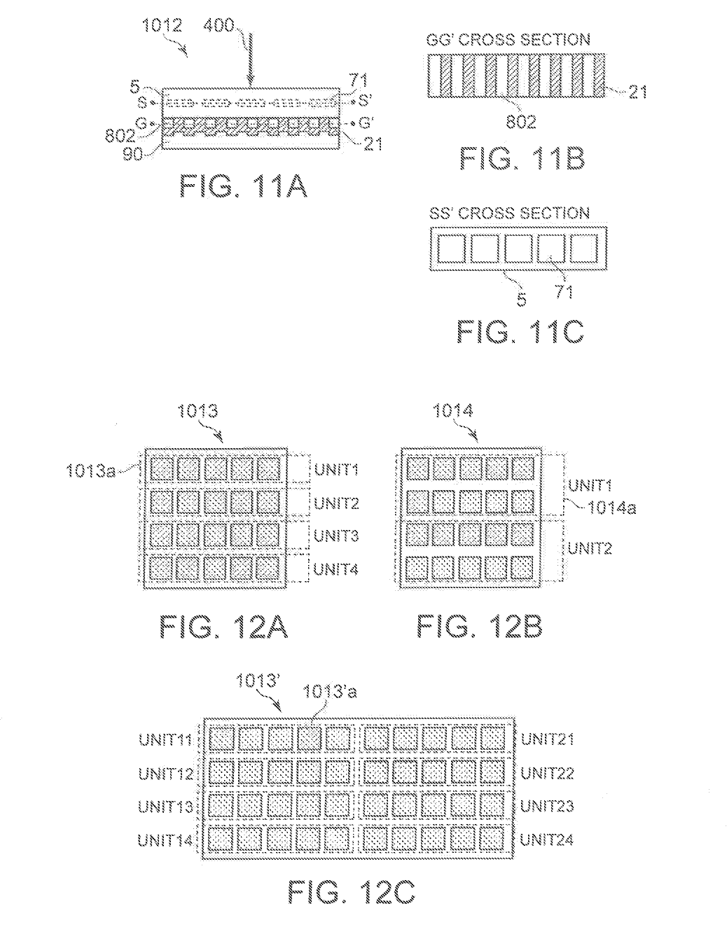

FIG. 11A is a diagram showing a photo detector of an eleventh embodiment.

FIG. 14B is a GG′ sectional vies of the photo detector of the eleventh embodiment.

FIG. 14C is as SS′ sectional view of the photo detector of the eleventh embodiment.

FIG. 15A is a diagram showing the photo detector of the eleventh embodiment.

FIG. 15B is a diagram shoeing characteristics of the photo detector of the eleventh embodiment.

FIG. 15C is a diagram showing characteristics of the photo detector of the eleventh embodiment.

FIG. 16A is a diagram showing a modification of the eleventh embodiment.

FIG. 16B is a GG′ sectional view of the modification of the eleventh embodiment.

FIG. 16C is an SS′ sectional view of the modification of the eleventh embodiment.

FIG. 17A is a diagram showing a photo detection device of a twelfth embodiment.

FIG. 17B is a diagram showing the photo detection device of the twelfth embodiment.

FIG. 18A is a diagram showing a manufacturing method of a photo detector.

FIG. 18B is a diagram showing the manufacturing method of a photo detector.

FIG. 18C is a diagram showing the manufacturing method of a photo detector.

FIG. 18D is a diagram stowing the manufacturing method of a photo detector.

FIG. 18E is a diagram showing the manufacturing method of a photo detector.

FIG. 18F is a diagram showing the manufacturing method of a photo detector.

FIG. 19A is a diagram showing a measuring system of a thirteenth embodiment.

FIG. 19B is a diagram showing a measuring system of the thirteenth embodiment.

FIG. 19C is a diagram showing a measuring system of the thirteenth embodiment.

FIG. 20 is a diagram showing a LIDAR device of a fourteenth embodiment

### DETAILED DESCRIPTION

According to one embodiment, a photo detector is provided with a semiconductor layer having a first light receiving surface and a second light receiving surface opposite to the first light receiving surface, and a diffraction grating which is provided on the first light receiving surface side of the semiconductor layer and has convex portions. The convex portions are arranged in one direction at. a predetermined cycle.

Hereinafter, further embodiments will be described with reference to the drawings. Ones with the same symbols show the similar ones. In addition, the drawings are schematic or conceptual, and accordingly, the relation between a thickness and a width in each portion, and a ratio coefficient of sizes between portions are not necessarily identical to those of the actual ones. In addition, even when the same portions are shown the dimensions and the ratio coefficients thereof may be shown differently depending on the drawings.

### First Embodiment

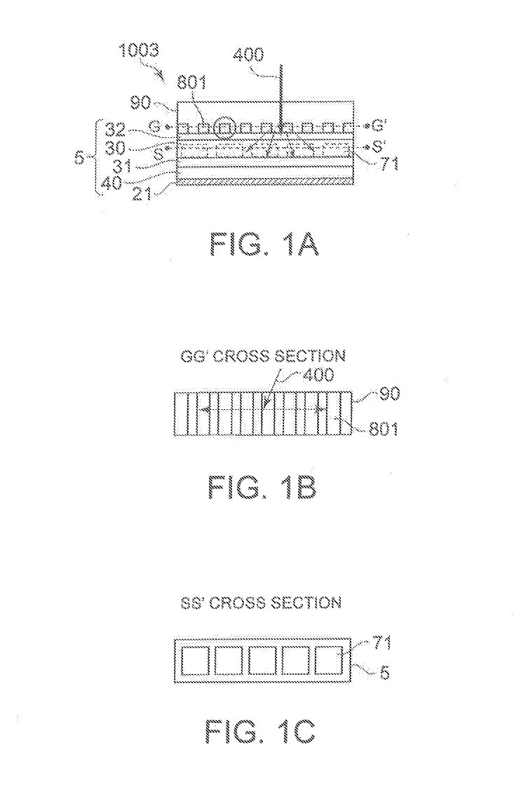

FIG. 1A is a diagram showing a photo detector 1003, FIG. 1B is a GG′ sectional view of the photo detector 1003, and FIG. 1C is an SS′ sectional view of the photo detector 1003.

In FIG. 1A, the photo detector 1003 is composed of a substrate 90, a one-dimensional diffraction grating (a diffraction grating) 801, a p⁺ type semiconductor layer 32, a p⁻ type semiconductor layer 30, a p⁺ type semiconductor layer 31, an n type semiconductor layer 40, a reflective material 21, a first electrode not shown, and an insulating layer not shown.

The p⁺type semiconductor layer 32, the p⁻ type semiconductor layer 30, the p⁺ type semiconductor layer 31, and the n type semiconductor layer 40 are collectively called a semiconductor layer 5. In the drawings described later, the description of the p⁺ type semiconductor layer 32, the p⁻ type semiconductor layer 30, the p⁺ type semiconductor layer 31, and the n type semiconductor layer 40 is omitted, and they will be described simply as the semiconductor layer 5.

The semiconductor layer 5 has a first light receiving surface and a second light receiving surface opposite to the first light receiving surface. For example, when the p⁺ type semiconductor layer 32 side is decided as the first light receiving surface, the n type semiconductor layer 40 side at a side opposite to the p⁺ type semiconductor layer 32 side becomes the second light receiving side.

The semiconductor layer 5 is composed of the p type semiconductor layer and the n type semiconductor layer in this order from the first light receiving surface toward the second light receiving surface.

That is, in the present embodiment, the semiconductor layer 5 is composed of the p⁺ type semiconductor layer 32, the p⁻ type semiconductor layer 30, the p⁺ type semiconductor layer 31, and the n type semiconductor layer 40 in this order, from the first light receiving surface toward the second light receiving surface.

In addition, the semiconductor layer 5 may not be provided with the p⁺ type semiconductor layers 31, 32, and may be a laminated structure of a p type semiconductor layer and an n type semiconductor layer. The semiconductor layer 5 may be composed of an n type semiconductor layer and a p type semiconductor layer in this order from the first light receiving surface toward the second light receiving surface. In addition, the semiconductor layer 5 may be composed of an n⁺ type semiconductor layer, an n⁻ type semiconductor layer, an n⁺ type semiconductor layer, and a p type semiconductor layer in this order, from the first light receiving surface toward the second light receiving surface. In addition, the laminated structure of the p⁺ type semiconductor layer 32, the p⁻ type semiconductor layer 30, the p⁺ type semiconductor layer 31, and the n type semiconductor layer 40, or the laminated structure of the n⁺ type semiconductor layer, the n⁻ type semiconductor layer, the n⁺ type semiconductor layer, and the p type semiconductor may be configured from the second light receiving surface toward the first light receiving surface.

In the photo detector 1003, the semiconductor layer 5 is composed of Si (silicon), for example. It is more preferable to select Si as the material of the semiconductor layer 5, because the manufacturing cost thereof is not expensive.

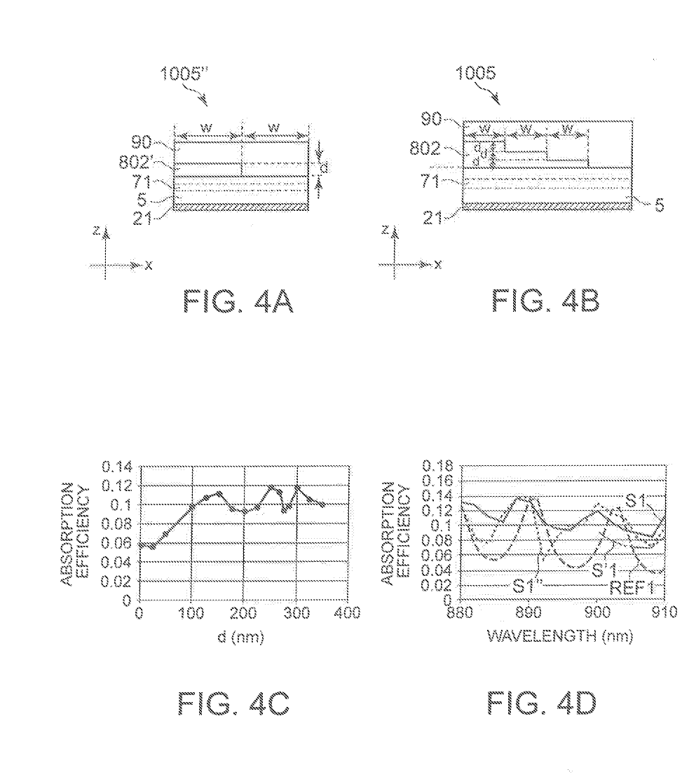

The one-dimensional diffraction grating 801 and the substrate 90 are provided at the first light receiving side of the semiconductor layer 5. The one-dimensional diffraction grating 801 is provided between the semiconductor layer 5 and the substrate 90. The one-dimensional diffraction grating 801 is arranged in one direction. The one-dimensional diffraction grating 801 has convex portions and concave portions. The convex portion and the concave portion are alternately arranged at a predetermined cycle. The convex portion and the concave portion are linear and in parallel with each other. An enlarged view of the one-dimensional diffraction grating 801 surrounded by a round frame in FIG. 1A is shown in each of FIGS. 4A, 4B described later.

The substrate 90 is provided on the first light receiving side of the semiconductor layer 5. The substrate 90 is provided on the one-dimensional diffraction grating 801 at a side opposite to the semiconductor layer 5. The substrate 90 transmits light. The substrate 90 supports the semiconductor layer 5. It is possible that the substrate 90 is not provided.

As shown also in FIG. 1C, a plurality of depletion layers 71 are provided one-dimensionally and separately from each other inside the semiconductor layer 5.

The reflective material 21 is provided on the second light receiving surface side of the semiconductor layer 5. The reflective material 21 reflects light incident into the semiconductor layer 5. The reflective material 21 may be provided with a function of an electrode as well. Because a refractive index of the semi conductor layer 5 is different from that of the outside of the semiconductor layer 5, light incident into the semiconductor layer 5 is reflected by an interface of the semiconductor layer 5 and the outside of the semiconductor layer 5. For the reason, it is possible that the reflective material 21 is not provided.

It is supposed that the light incident into the p⁺ type semiconductor layer 32 serving as the light receiving surface is near infrared light with a wavelength of not less than 750 nm and not more than 1000 nm.

A length of the semiconductor layer 5 in a direction from the light receiving surface toward the reflective material 21 is not less than 1 μm and not more than 15 μm.

The substrate 90 may be adhered to the semiconductor layer 5 via an adhesive layer not shown, for example.

Here, a light 400 is incident from the p⁺ type semiconductor layer 32 serving as the light receiving surface of the photo detector 1003. The incident light 400 is absorbed by the depletion layer 71 formed by the p⁺ type semiconductor layer 31 and the p⁻ type semiconductor layer 30. The incident light 400 is converted into electron-hole pairs in the depletion layer 71.

When a voltage serving as a reverse bias is applied between the pn junction of the p⁻ type semi conductor layer 30 and the n type semiconductor layer 40, electrons of the electron-hole pairs flow in the direction of the n type semiconductor layer 40. Holes of the electron-hole pairs flow in the direction of the p⁺ type semiconductor layer 32. At this time, if the voltage is increased, the flowing speeds of the electrons and the holes are accelerated in the depletion layer 71. Particularly, in the p⁺ type semiconductor layer 31, electrons come in collision with atoms in the p⁻ type semiconductor layer 30, to generate new electron-hole pairs. This phenomenon is called avalanche amplification. The avalanche amplification is a reaction which occurs in chains. The avalanche amplification is generated, and thereby the photo detector 1003 can detect weak light.

A thickness d of the semiconductor layer 5 between the first electrode and the reflective material 21 is 1-15 for example. If this thickness d is smaller than 1 μm, a region of the depletion layer 71 becomes small. Accordingly, a detection efficiency and an amplification factor of light of the photo detector 1003 become low. If the thickness d is larger than 15 μm, it becomes necessary to apply a high voltage when electrodes are respectively provided on the both ends of the semi conductor layer 5. In addition, the increase of light absorption outside the depletion layer 71, occurs, and causes reduction of the light detection efficiency.

In the photo detector 1003, a dead time when light cannot be detected is generated after the avalanche amplification has occurred. The dead time of the photo detector 1003 is made short, and thereby the photo detector 1003 can detect light efficiently. In order to make the dead time of the photo detector 1003 short, it is necessary to promptly take out the electrons and holes existing inside the photo detector 1003 to the outside. At this time, a speed at which the electrons and holes are taken out to the outside of the photo detector 1003 is determined by an capacitance C of the photo detector 1003. The capacitance C depends on an area S of the p⁺ type semiconductor layer 32 serving as the light receiving surface. The smaller the area S of the p⁺ type semiconductor layer 32 serving as the light receiving surface is, the smaller the capacitance C of the photo detector 1003 becomes. The smaller the area S of the p⁺ type semiconductor layer 32 serving as the light receiving surface is, the more promptly the electrons and holes existing inside the photo detector 1003 can be taken out to the outside.

Accordingly, it is preferable that the area S of the p⁺ type semiconductor layer 32 serving as the light receiving surface is not more than 100 μm×100 μm. On the other hand, when the area S of the p⁺ type semiconductor layer 32 serving as the light receiving surface is too small, the detection sensibility of the photo detector 1003 is decreased. In order to make the reduction of the dead time compatible with the detection sensibility of light, it is preferable that the area S of the p⁺ type semiconductor layer 32 serving as the light receiving surface is 25 μm×25 μm, for example.

In the GG′ sectional view of FIG. 1B, this incident light 400 is diffracted by the one-dimensional diffraction grating 801, and proceeds in a direction in which the one-dimensional diffraction grating 801 is arranged.

In the SS′ sectional view of FIG. 1C, the depletion layers 71 are arranged in the same direction as the one-dimensional diffraction grating 801. Accordingly, the direction in which the light 400 proceeds by the one-dimensional diffraction grating 801 and the direction in which a plurality of the depletion layers 71 are arranged are the same. The light 400 is diffracted by the one-dimensional diffraction grating 801, and is absorbed by the plurality of depletion layers 71.

A plurality of the depletion layers 71 are provided as in the case of the photo detector 1003, even though an area of each of the depletion layers 71 is not made large, a detection area of light of the depletion layer 71 is maintained, and thereby a high speed response is enabled. Because light can be diffracted only in a specific direction by the one-dimensional diffraction grating 801, it is possible to realize a photo detector with higher space-saving property and higher efficiency, than a photo detector 1004 using a two-dimensional diffraction grating which will be described later.

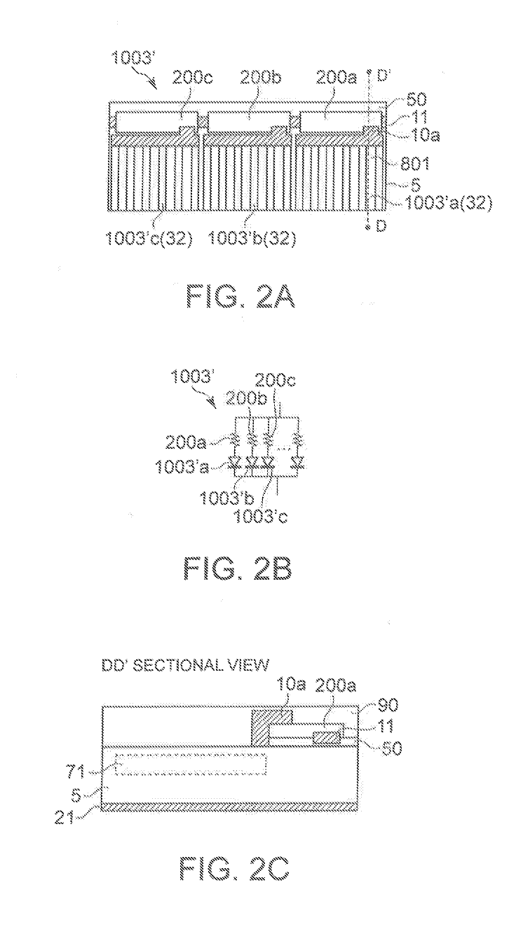

FIG. 2A is a diagram showing a photo detector 1003′ that is the photo detector 1003 seen from the diffraction grating 801 side, FIG. 2B is a circuit diagram of the photo detector 1003′, and FIG. 2C is a DD′ sectional view of the photo detector 1003′.

In the photo detector 1003′ of FIG. 2A, quench resistors 200a, 200b, 200c are provided outside the region of the p⁺ type semiconductor layer 32 serving as the light receiving surface.

An insulating layer 50 is provided between the quench resistors 200a, 200b, 200c and the semiconductor layer 5. The quench resistors 200a, 200b, 200c are connected to photo detection regions 1003′a, 1003′b, 1003′c; via first electrodes 10a, respectively. Each of the photo detection regions 1003′a, 1003′b, 1003′c is the p⁺ type semiconductor layer 32 serving as the light receiving surface.

When the quench resistors 200a, 200b, 200c and the first electrodes 10a are respectively provided corresponding to the photo detection regions 1003′a, 1003′b, 1003′c, it is possible to make the depletion layers corresponding to the respective photo detection regions 1003′a, 1003′b, 1003′c inside the semiconductor layer 5.

Wires 11 are provided between the quench resistors 200a, 200b, 200c and the insulating layer 50, respectively. The wires 11 connect among the quench resistor 200a, the quench resistor 200a and the quench resistor 200c.

In FIGS. 2B, 2C, the quench resistor 200a is connected to the photo detection region 1003′a. The quench resistor 200b is connected to the photo detection region 1003′b. The quench resistor 200c is connected to the photo detection region 1003′c.

The photo detection regions 1003′a, 1003′b, 1003′c are connected in parallel with each other via the quench resistors 200a, 200b, 200c, respectively.

The photo detector 1003′ is composed of the photo detection regions 1003′a, 1003′b, 1003′c, but the outputs of them are subjected to signal processing as one output.

### Modification 1 of First Embodiment

Hereinafter, a modification of the first embodiment for showing an effect of the above-described photo detector 1003 is shown.

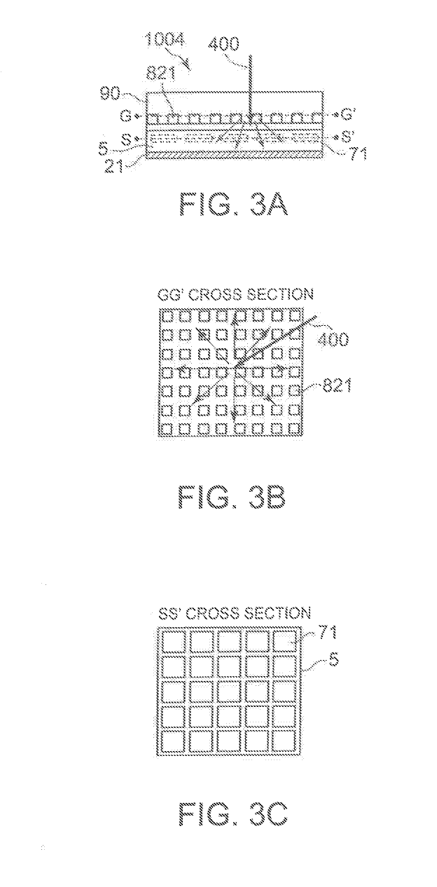

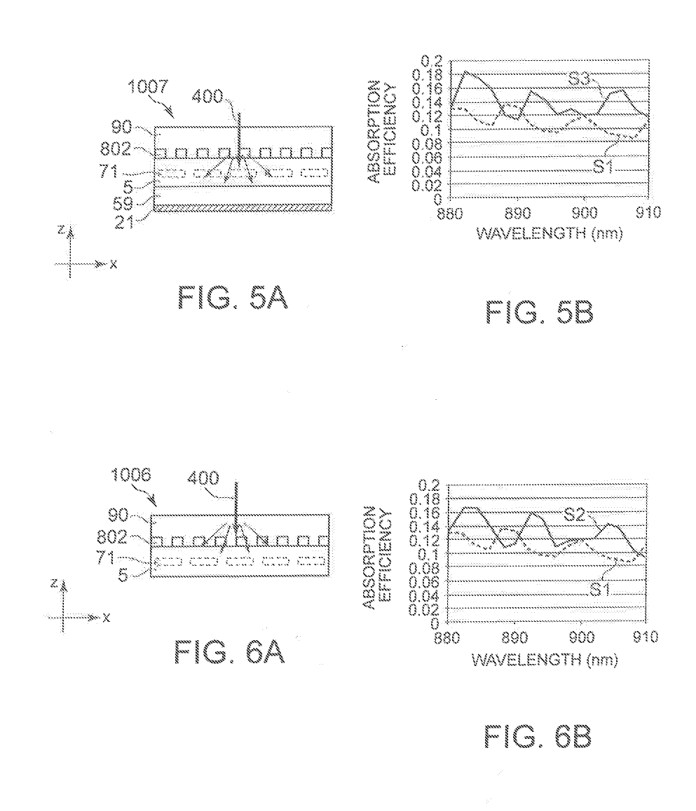

FIG. 3A is a diagram showing a photo detector 1004, FIG. 5B is a GG′ sectional view of the photo detector 1004, and FIG. 3C is an SS′ sectional view of the photo detector 1004.

The same symbols are given to the same portions as in FIG. 1A, and the description thereof will be omitted.

In FIG. 3A, the photo detector 1004 is provided with a two-dimensional diffraction grating 821. The two-dimensional diffraction grating 821 is provided on the light receiving surface side of the semiconductor layer 5. The two-dimensional diffraction grating 821 is provided between the semiconductor layer 5 and the substrate 90. The two-dimensional diffraction grating 821 is two-dimensionally arranged within the whole surface of the first light receiving surface. The two-dimensional diffraction grating 821 has convex portions and a concave portion. In the two-dimensional diffraction grating 821, the convex portions are arranged two-dimensionally. The convex portions are arranged at a predetermined cycle.

In the photo detector 1004, the incident light 400 is diffracted by the two-dimensional diffraction grating 821. The light 400 is detected by a plurality of the depletion layers 71.

In FIG. 3B, the incident light 400 is diffracted within the whole surface of the first light receiving surface by the two-dimensional diffraction grating 821.

In FIG. 3C, the plurality of depletion layers 71 are two-dimensionally arranged within the whole surface inside the semiconductor layer 5. The plurality of depletion layers 71 absorb the light 400 diffracted by the two-dimensional diffraction grating 821.

Accordingly, in a case of detecting a large portion of the diffracted light 400, the depletion layers 71 have to be provided two-dimensionally and broadly. On the other hand, in the photo detector 1003, the light 400 is diffracted in a specified direction by the one-dimensional diffraction grating 801, and accordingly, the light 400 is not diffused within the surface thereof. In the photo detector 1003, it is only necessary to provide a smaller number of the depletion layers 71, compared with the photo detector 1004.

### Second Embodiment

FIG. 4A is a diagram showing a photo detector 1005″, FIG. 4B is a diagram showing a photo detector 1005, FIG. 4C is a diagram showing the relation between a height d of the photo detector 1005 and a light absorption efficiency, and FIG. 4D is a diagram showing light absorption efficiencies of the photo detectors 1005″, 1005.

The same symbols are given to the same portions as in FIG. 1A, and the description thereof will be omitted.

The photo detector 1005″ of FIG. 4A is an enlarged view of the convex portion of the one-dimensional diffraction grating 801 surrounded by the round frame in FIG. 1A.

In FIG. 4A, the photo detector 1005″ is obtained by replacing the one-dimensional diffraction grating 801 of the photo detector 1003 by a stepwise one-dimensional diffraction grating 802′. FIG. 4A shows one cycle portion of the stepwise one-dimensional diffraction grating 802′.

The stepwise one-dimensional diffraction grating 802′ has a step and is stepwise. A height of the stepwise one-dimensional diffraction grating 802′ per step is decided as d. A length (width) of the stepwise one-dimensional diffraction grating 802′ in the horizontal direction per step is decided as w. The stepwise one-dimensional diffraction grating 802′ is composed of the same material as the semiconductor layer 5, for example.

The photo detector 1005 of FIG. 4B is an enlarged view of the convex portion of the one-dimensional diffraction grating 801 surrounded by the round frame in FIG. 1A, and the photo detector 1005 is obtained by replacing the convex portion of the one-dimensional diffraction grating 801 by a convex portion of a stepwise one-dimensional diffraction grating 802. The photo detector 1005 is provided with the stepwise one-dimensional diffraction grating 802, as a modification of the one-dimensional diffraction grating 801 of the photo detector 1003. FIG. 4B shows one cycle portion of the stepwise one-dimensional diffraction grating 802.

The stepwise one-dimensional diffraction grating 802 has a stepwise shape with a plurality of steps. The stepwise one-dimensional diffraction grating 802 has more steps than the above-described stepwise one-dimensional diffraction grating 802′. A height of the stepwise one-dimensional diffraction grating 802 per step is decided as d. A length (width) of the stepwise one-dimensional diffraction grating 802 in the horizontal direction per step is decided as w. The stepwise one-dimensional diffraction grating 802 is composed of the same material as the semiconductor layer 5, for example.

FIG. 4C shows the relation between a value of the height d per step of the stepwise one-dimensional diffraction grating 802 of the photo detector 1005 and a light absorption efficiency.

FIG. 4C is calculated by simulation. The condition of simulation was that the substrate 90 is made of glass, the semiconductor layer 5 is made of silicon with a thickness of 8 μm, the reflective material 21 is made of aluminum with a thickness of 200 nm. In addition, a length (width) of the depletion layer 71 in the horizontal direction is 2 μm, and the light is a randomly polarized light with a wavelength of 900 nm. The length (width) w of the stepwise one-dimensional diffraction grating 802 per step in the horizontal direction is 400 nm. In addition, this simulation was calculated with a finite difference time domain method, and a periodic boundary condition was used for the x direction, and a completely absorption boundary condition was used for the y direction. The cyclic boundary condition was used for the x direction, and thereby the depletion layers 71 serving as detector regions are arranged in the x direction.

It is found from FIG. 4C that a light absorption efficiency of the photo detector 1005 is more improved, by providing the stepwise one-dimensional diffraction grating 802 (d≠0), than a case in which the stepwise one-dimensional diffraction grating 802 is not provided (d=0). The stepwise one-dimensional diffraction grating 802 is provided, and thereby it becomes easy to confine the light inside the semiconductor layer 5.

FIG. 4D is calculated by simulation. The condition of simulation was that the lengths (widths) w of the stepwise one-dimensional diffraction gratings 802′, 802 per step are 400 nm, and the heights d are 250 nm, respectively. Each of the stepwise one-dimensional diffraction gratings 802′, 802 is made of silicon. The other conditions are the same as in FIG. 4C.

S1″ shows a light absorption efficiency of the photo detector 1005″, and S1 shows a light absorption efficiency of the photo detector 1005. In addition, in FIG. 4D, a light absorption efficiency REF1 of a photo detector of a comparative example 1 is also shown for reference. REF1 of the comparative example 1 is a light absorption efficiency of the photo detector 1003 in which the one-dimensional diffraction grating 801 is not provided.

Further, in FIG. 4D, a light absorption efficiency S′1 of the photo detector 1005 is also shown for reference, in a case in which not a periodic boundary condition but a finite region is used for the x direction in the photo detector 1005. S′1 was calculated by simulation in which a width of the depletion layer 71 in the x direction is 20 μm.

The wavelength dependencies of light of S1″ and S1 are more suppressed than that of REF1, and S1″ and S1 realize high absorption efficiencies of light. S1 has lower wavelength dependency of a light absorption efficiency than S1″. Accordingly, the photo detector 1008 realizes a more stable light absorption efficiency than the photo detector 1005″. The more the number of steps of the stepwise one-dimensional diffraction grating 802 is made, the more the wavelength dependency of the light absorption efficiency of the photo detector 1005 is suppressed. Accordingly, the more the number of steps of the stepwise one-dimensional diffraction grating 802 is made, the more stable light absorption efficiency the photo detector 1005 realizes.

### Third Embodiment

FIG. 5A is a diagram showing a photo detector 1007, FIG. 5B is a diagram showing a light absorption efficiency of the photo detector 1007.

In FIG. 5A, the photo detector 1007 is further provided with a path separation layer (a spacer layer) 59 in the photo detector 1005. The same symbols are given to the same portions as in FIG. 1A, and the description thereof will be omitted.

The path separation layer 59 is provided between the semiconductor layer 5 and the reflective material 21. A refractive index of the path separation layer 59 is lower than a refractive index of the semiconductor layer 5. The path separation layer 59 is composed of a film of an oxide such as SiO₂, a film of a nitride such as SiN, for example,

The light 400 diffracted by the stepwise one-dimensional diffraction grating 802 is totally reflected by an interface of the semiconductor layer 5 and the path separation layer 59. The light 400 is confined within the semiconductor layer 5.

The light 400 which has not been totally reflected by the interface of the semiconductor layer 5 and the path separation layer 59 is reflected by an interface of the path separation layer 50 and the reflective material 21, and is incident into the semiconductor layer 5.

The photo detector 1007 reduces reflection loss of light in the reflective material 21 by the path separation layer 59.

FIG. 5B shows wavelength dependency of a light absorption efficiency (S3) of the photo detector 1007.

FIG. 5B is calculated by simulation. The condition of simulation was that the substrata 90 is made of glass, the semiconductor layer 5 is made of silicon with a thickness of 8 μm, the reflective material 21 is made of aluminum with a thickness of 200 nm. In addition, a width of the depletion layer 71 is 2 μm. The light 400 is a randomly polarized light. The width w of the stepwise one-dimensional diffraction grating 802 per step is 400 nm, the height d is 250 nm. The stepwise one-dimensional diffraction grating 802 is composed of silicon. A thickness of the path separation layer 50 is 1.1 μm. A refractive index of the path separation layer 59 is about 1.5.

A light absorption efficiency (S1) of the above-described photo detector 1005 is also shown in FIG. 5B. As shown in FIG. 5B, S3 realizes a higher light absorption efficiency than S1.

### Fourth Embodiment

FIG. 6A is a diagram showing a photo detector 1006, and FIG. 6B is a diagram showing a light absorption efficiency of the photo detector 1006.

In FIG. 6A, the photo detector 1006 is not provided with the reflective material 21 in the photo detector 1005. The same symbols are given to the same portions as in FIG. 1A, and the description thereof will be omitted.

The light 400 incident into the photo detector 1006 is diffracted by the stepwise one-dimensional diffraction grating 802. The diffracted light is incident into the semiconductor layer 5, and is totally reflected by an interface of the semiconductor layer 5 at a side opposite to the first light receiving surface of the semiconductor layer 5 and the outside. A reflectance when the light 400 is totally reflected by the interface of the semiconductor layer 5 and the outside is higher than a reflectance when the light is reflected by the reflective material 21 of the photo detector 1005. For the reason, the photo detector 1006 realizes a higher light absorption efficiency than the photo detector 1005.

FIG. 6B shows wavelength dependency of a light absorption efficiency (S2) of the photo detector 1006.

FIG. 6B is calculated by simulation. The condition of simulation was that the substrate 90 is made of glass, the semiconductor layer 5 is made of silicon with a thickness of 8 μm. In addition, a length (width) of the depletion layer 71 in the horizontal direction is 2 μm. The light 400 is a randomly polarized light. The length (width) w of the stepwise one-dimensional diffraction grating 802 per step is 400 nm, and the height d thereof is 250 nm. The stepwise one-dimensional diffraction grating 802 is composed of silicon.

In FIG. 6B, the light absorption efficiency (S1) of the above-described photo detector 1005 is shown. S2 realizes a higher light absorption efficiency than S1.

### Fifth Embodiment

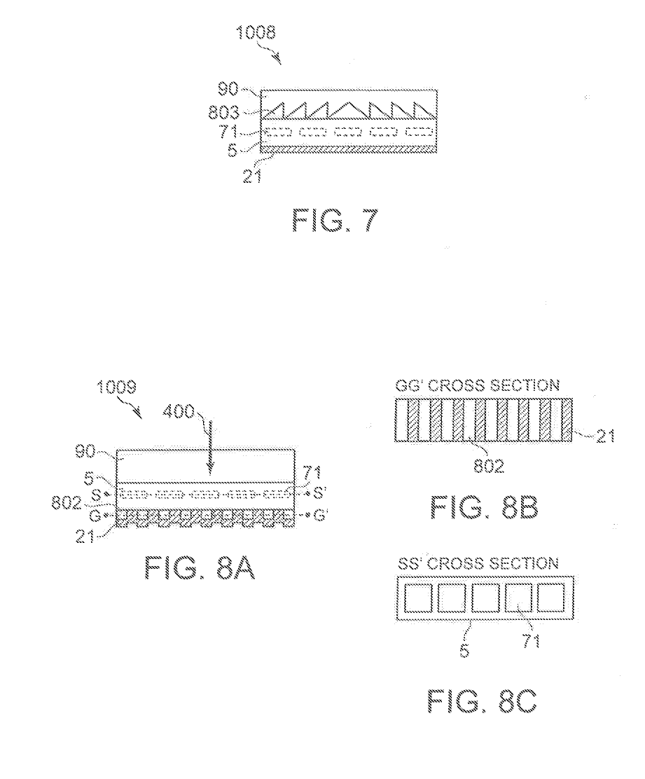

FIG. 7 is a diagram showing a photo detector 1008.

The same symbols are given to the same portions as in FIG. 1A, and the description thereof will be omitted.

The photo detector 1008 is provided with a one-dimensional diffraction grating (diffraction grating) 803, as the one-dimensional diffraction grating (diffraction grating) in the photo detector 1003.

The one-dimensional diffraction grating 803 is a blazed (saw-tooth) phase diffraction grating. In the one-dimensional diffraction grating 803, two kinds of blazed phase diffraction gratings with different blaze directions face to each other. The one-dimensional diffraction grating 803 may be made a stepwise diffraction grating. It is known that the one-dimensional diffraction grating 803 can be designed so as to make a diffraction efficiency to a specific diffraction order high. Accordingly, the blasé directions are faced so that the lights are diffracted to the center of the photo detector 1008, the lights hardly escape to the outside of the photo detector 1008. For the reason, in the photo detector 1008, a high detection efficiency of light is realized.

In addition, a position of the contact point of the two blazed phase diffraction gratings of the one-dimensional diffraction grating 803 is not necessarily the center of the photo detector 1008.

### Sixth Embodiment

FIG. 8A is a diagram showing a photo detector 1009, FIG. 8B is a GG′ sectional view of the photo detector 1008, and FIG. 8C is an SS′ sectional view of the photo detector 1009.

The same symbols are given to the same portions as in FIG. 1A, and the description thereof will be omitted.

In the photo detector 1009, the stepwise one-dimensional diffraction grating 802 is provided on the second light receiving surface side of the semiconductor layer 5. The substrate 90 is provided on the first light receiving surface side of the semiconductor layer 5. The reflective material 21 is provided on the stepwise one-dimensional diffraction grating 802 at a side opposite to the semiconductor layer 5 side.

The stepwise one-dimensional diffraction grating 802 diffracts the light 400 which has passed through the semiconductor layer 5. The diffracted light 400 is reflected by the reflective material 21 toward the depletion layer 71 of the semiconductor layer 5.

As shown in FIG. 8B and FIG. 8C, the stepwise one-dimensional diffraction grating 802 is arranged in accordance with the arrangement direction of the depletion layers 71.

### Seventh Embodiment

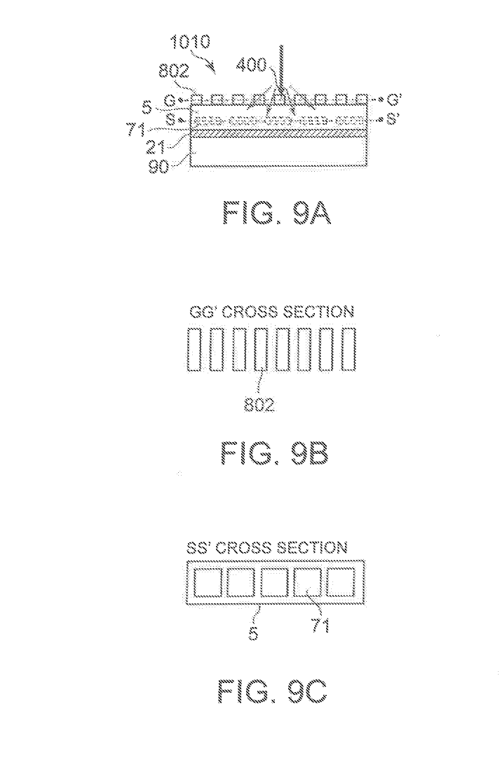

FIG. 9A is a diagram showing a photo detector 1010, FIG. 9B is a GG′ sectional view of the photo detector 1010, and FIG. 8C is an SS′ sectional view of the photo detector 1010.

The same symbols are given to the same portions as in FIG. 8A, and the description thereof will be omitted.

In the photo detector 1010, the reflective material 21 is provided between the substrate 90 and the semiconductor layer 5. The light incident from the first light receiving surface of the semiconductor layer 5 is diffracted by the stepwise one-dimensional diffraction grating 802. The diffracted light is absorbed by the depletion layer 71. The light which has once passed through the depletion layer 71 out of the diffracted light is reflected by the reflective material 21 and is absorbed by the depletion layer 71.

As shown in FIG. 9B and FIG. 9C, the stepwise one-dimensional diffraction grating 802 is arranged in accordance with the arrangement direction of the depletion layers 71.

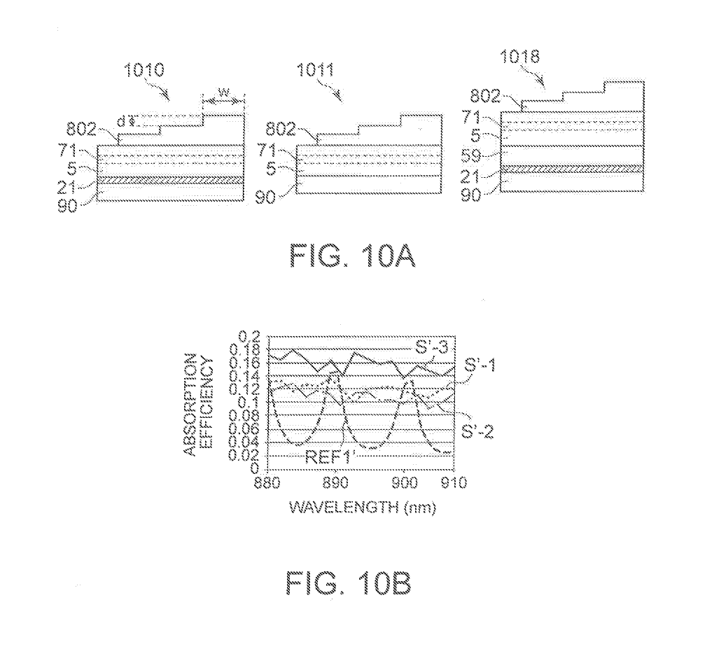

FIG. 10A is a diagram showing photo detectors 1010, 1011, 1018, and FIG. 10B is a diagram showing wavelength dependency of a light absorption efficiency in the photo detectors 1010, 1011, 1018.

The same symbols are given to the same portions as in FIG. 9A, and the description thereof will be omitted.

FIG. 10A is a diagram in which the convex portion of the stepwise one-dimensional diffraction grating 802 of the photo detector 1010 of FIG. 9A is enlarged.

Further, as shown in FIG. 10A, the photo detector 1011 is not provided with the reflective material 21 in the photo detector 1010. The photo detector 1018 is provided with the path separation layer (spacer layer) 58 between the semiconductor layer 5 and the substrate 90 in the photo detector 1010.

In FIG. 10B, S′-1 shows a light absorption efficiency of the photo detector 1010, S′-2 shows a light absorption efficiency of the photo detector 1011, and S′-3 shows a light absorption efficiency of the photo detector 1018.

FIG. 10B is calculated by simulation. The condition of simulation was that the substrate 90 is made of glass, the semiconductor layer 5 is made of silicon with a thickness of 8 μm, the reflective material 21 is made of aluminum with a thickness of 200 nm. A width of the depletion layer 71 is 2 μm. The light 400 is a randomly polarized light. The width w of the stepwise one-dimensional diffraction grating 802 per step is 400 nm, and the height d is 250 nm. The stepwise one-dimensional diffraction grating 302 is composed of silicon. A thickness of the path separation layer 59 of the photo detector 1018 is 1.1 μm, and a refractive index thereof is about 1.5.

For reference, a light absorption efficiency REF1′ is also shown in a case in which the stepwise one-dimensional diffraction grating 802 is not provided in the photo detector 1010.

As shown in FIG. 10B, each of S′-1, S′-2, and S′-3 realizes a higher light absorption efficiency than REF1′. Particularly, S′-3 realizes the highest light absorption efficiency among them.

### Eighth Embodiment

FIG. 11A is a diagram showing a photo detector 1012, FIG. 11B is a GG′ sectional view of the photo detector 1012, and FIG. 11 is an SS′ sectional view of the photo detector 1012.

The same symbols are given to the same portions as in FIG. 1A and FIG. 8A, and the description thereof will be omitted.

The substrate 90 is provided on the reflective material 21 at a side opposite to the stepwise one-dimensional diffraction grating 802 side. The light incident from the first light receiving surface side is absorbed by the depletion layer 71. The light which has once passed through the depletion layer 71 out of the light incident from the first light receiving surface side is diffracted by the stepwise one-dimensional diffraction grating 802, and further reflected by the reflective material 21 and is absorbed by the depletion layer 71.

As shown in FIG. 11B and FIG. 11C, the stepwise one-dimensional diffraction grating 802 is arranged in accordance with the arrangement direction of the depletion layers 71.

### Ninth Embodiment

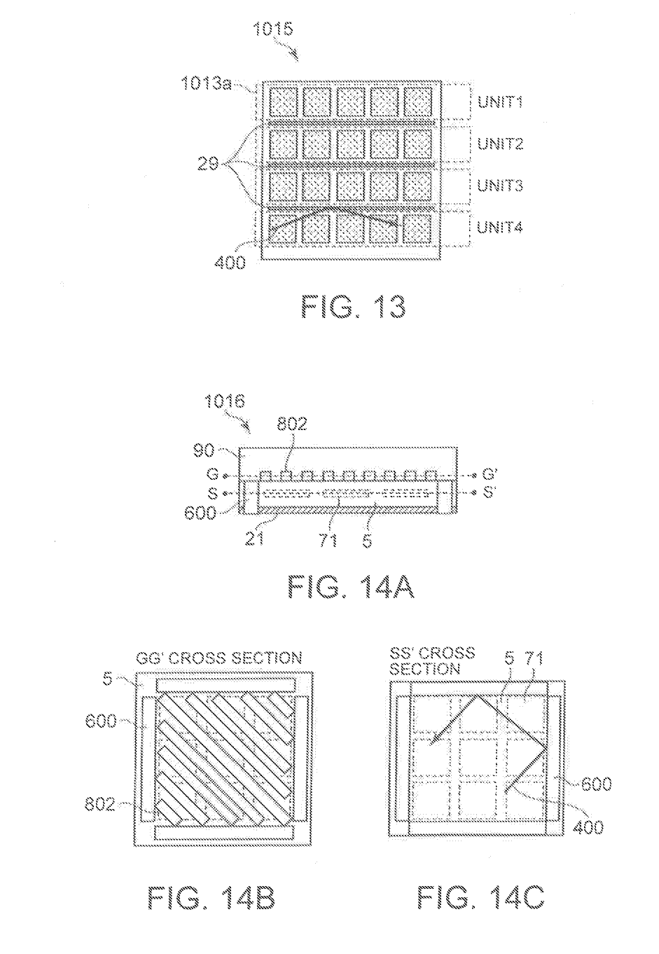

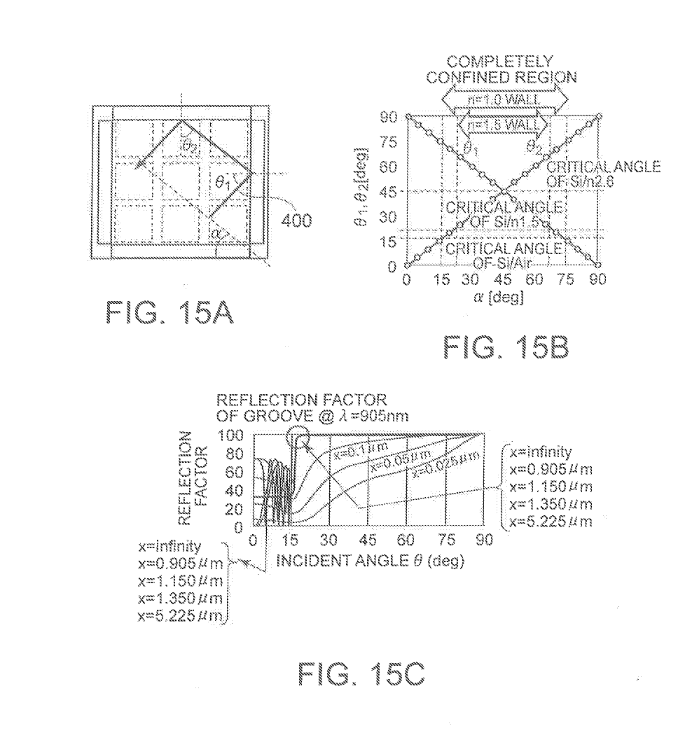

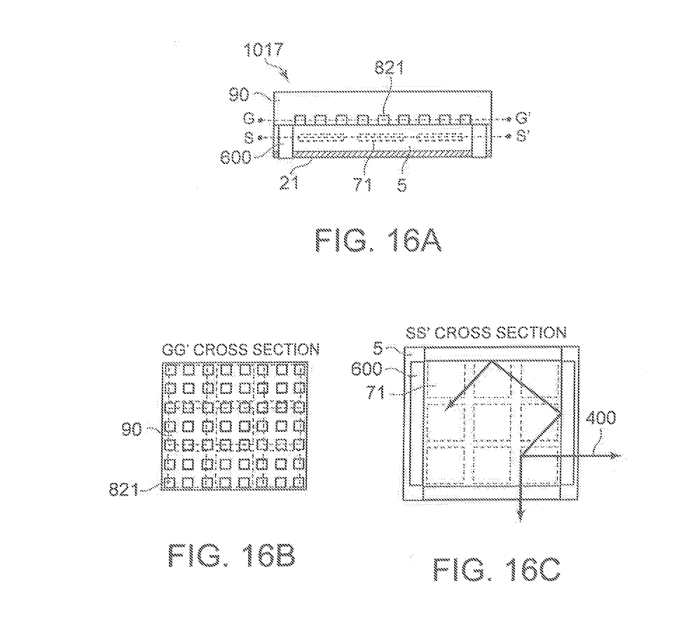

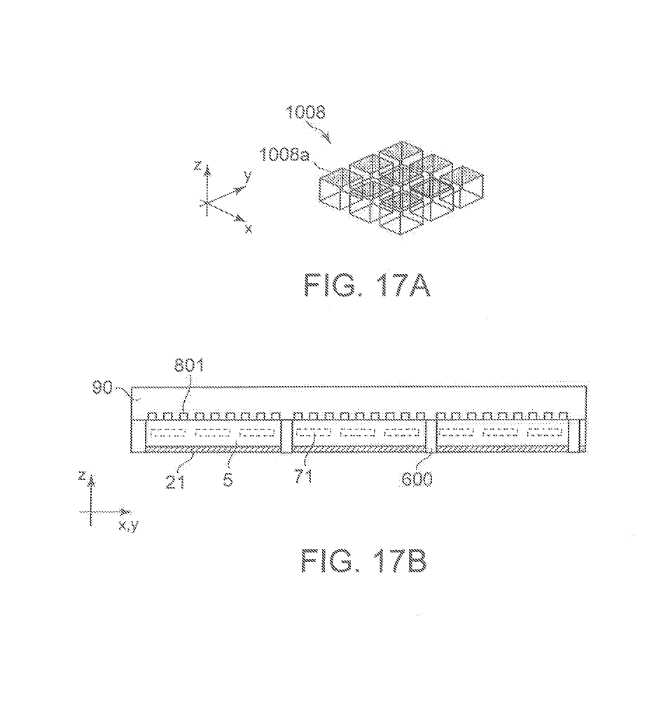

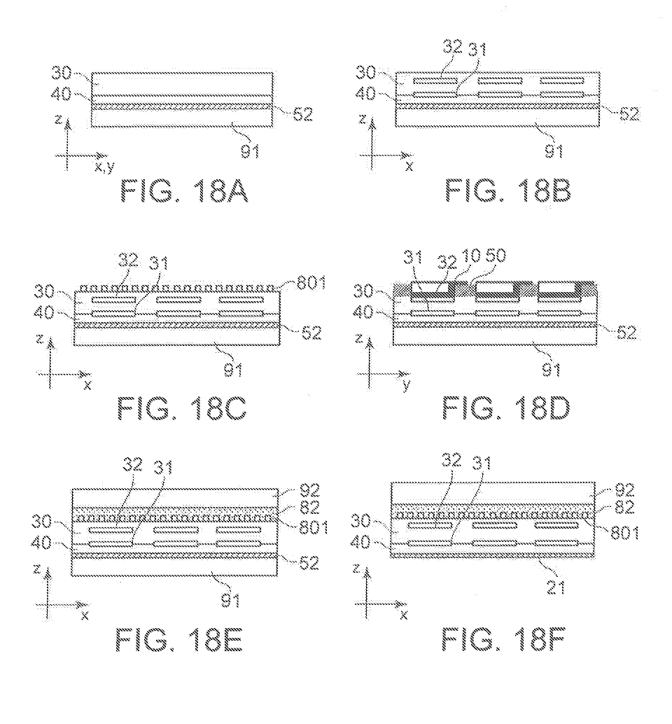

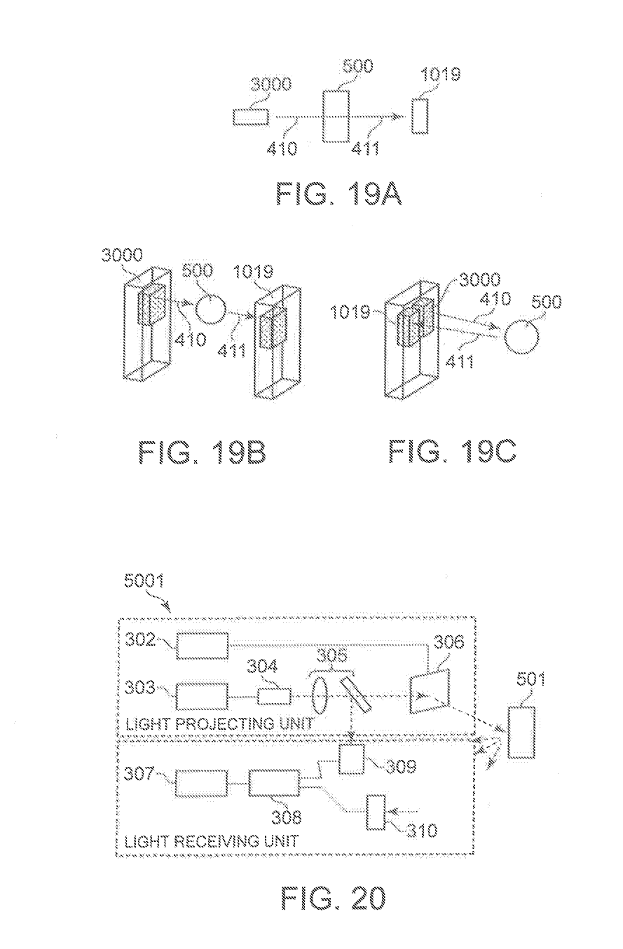

FIG. 12A is a diagram showing a photo detection device 1013, FIG. 12B is a diagram showing a photo detection device 1014, and FIG. 12C is a diagram showing a photo detection device 1013′.

In FIG. 12A, the photo detection device 1013 is composed of a plurality of photo detectors 1013a. Units 1-4 in FIG. 12A are each the photo detector 1013a. In the photo detection device 1013, the plurality of photo detectors 1013a are arranged one-dimensionally. Each of the plurality of photo detectors 1013a is the photo detector according to any of the above-described first to eighth embodiments. The light receiving surfaces of the plurality of photo detectors 1013a are arranged two-dimensionally. The photo detection device 1013 can obtain one-dimensional position information of the detected light, and so on.

In FIG. 12B, the photo detection device 1014 is composed of a plurality of photo detectors 1014a. The units 1-2 in FIG. 12B are each the photo detector 1014a. In the photo detection device 1014, the photo detectors 1014a are arranged one-dimensionally. Each of the plurality of photo detectors 1014a is the photo detector according to any of the above-described first to eighth embodiments. The light receiving surfaces of the plurality of photo detectors 1014a are arranged two-dimensionally. The photo detector 1014a outputs one output signal as the photo detector 1003′ shown in FIG. 2A. The photo detection device 1014 can obtain one-dimensional position information of the detected light.

In FIG. 12C, the photo detection device 1013′ is composed of a plurality of photo detectors 1013′a. Units 11-24 in FIG. 12C are each the photo detector 1013′a. In the photo detection device 1013′, the photo detectors 1013′a are arranged two-dimensionally. Each of the photo detector 1013′a is the photo detector of any of the first to eighth embodiments. The light receiving surfaces of the plurality of photo detectors 1013′a are arranged two-dimensionally. The photo detection device 1013′ can obtain two-dimensional position information of the detected light, and so on.

### Tenth Embodiment

FIG. 13 is a diagram showing a photo detection device 1015.

The photo detection device 1015 is further provided with reflection walls 29 in the photo detection device 1013 of FIG. 12A. For example, each of the reflection walls 29 is provided between the photo detector 1013a and the photo detector 1013a. When the light 400 is not sufficiently diffracted by the one-dimensional diffraction grating of the photo detector 1013a, the reflection wall 29 plays a role to return the light 400 which has gone outside the detection region to the detection region again. When the cycle direction of the one-dimensional diffraction grating and the arrangement direction of the detection regions within the photo detector do not sufficiently coincide with each other, the reflection wall 29 is effective.

### Eleventh Embodiment

FIG. 14A is a diagram showing a photo detector 1016. FIG. 14B is a GG′ sectional view of the photo detector 1016, and FIG. 14C is an SS′ sectional view of the photo detector 1016.

The same symbols are given to the same portions as in FIG. 1A, and the description thereof will be emitted.

In the photo detector 1016 of FIG. 14A, the cycle direction of the stepwise one-dimensional diffraction grating 802 is different from the arrangement direction of the depletion layers 71. In addition, in the photo detector 1016, a groove (void portion) 600 is provided in at least a part of the periphery of the first light receiving surface.

In the GG′ sectional view of FIG. 14B, the cycle direction of the stepwise one-dimensional diffraction grating 802 is inclined to the arrangement direction of the depletion layers 71 by 45 degrees, for example. Dotted lines shown in FIG. 14B show the positions of the depletion layers 71 inside the semiconductor layer 5.

In the SS′ sectional view of FIG. 14C, the grooves 600 are provided so as to surround the whole or a part of the periphery of the depletion layer 71 region.

In the photo detector 1016, when the light 400 is diffracted by the stepwise one-dimensional diffraction grating 802, it is incident into the groove 600. Since the cycle direction of the stepwise one-dimensional diffraction grating 802 and the arrangement direction of the depletion layers 71 are different, the light 400 which has been diffracted by the stepwise one-dimensional diffraction grating 802 has a specific incident angle to the groove 600. Since the groove 600 is filled with air, for example, the light 400 is totally reflected by the interface of the semiconductor layer 5 and the groove 600. Since the totally reflected light 400 is also totally reflected by the other groove 600 in the same manner, the light 400 is confined within the detection region surface.

FIG. 15A is a diagram showing a condition to confine the light within the detection region. FIG. 15B is a diagram showing the relation between an angle α and angles θ₁, θ₂, and FIG. 15C is a diagram showing the relation between an angle θ and a reflectance of the groove 600.

FIG. 15A is a diagram of the photo detector 1016 when seen from the first light receiving surface side. Here, it is assumed that the semiconductor layer 5 is silicon, and the groove 600 is filled with air. When an angle formed by the linearly arranged convex portions or concave portions of the stepwise one-dimensional diffraction grating 802 and the groove 600 is α, the light 400 is incident to the interface between air and the semiconductor layer 5 in the groove 600 at an incident angle θ₁.

FIG. 15B shows the relation between the angle α and the angle θ₁.

The horizontal axis shows the angle α, and the vertical axis shows an angle θ₁. And the vertical axis also shows an angle θ₂ described later.

The condition in which the light 400 is totally reflected by the interface in the groove 600 is that θ₁ is not less than 15.8 (deg). Accordingly, the angle α is also decided as 15.8 (deg). Further, when the totally reflected light 400 has been incident into another interface of the groove 600 at the incident angle θ₂, it is necessary to make the incident angle θ₂ 15.8 (deg), so as to make the light 400 to be totally reflected. At this time, since the angle α is expressed by 90−θ₂ (deg), the angle α becomes 90−15.8 (deg). Accordingly, when regarding the angle α formed by the linearly arranged convex portions or concave portions and the groove 600, 15.8 (deg)≦α≦90−15.8 (deg), it is possible to completely confine the light 400 within the photo detection region.

FIG. 15C shows the relation between the length (width) x of the groove 600 in the horizontal direction and a reflectance of light of the interface in the groove 600.

The horizontal axis shows the incident angle θ₁ (θ₂), and the vertical axis shows the reflectance.

FIG. 15C is calculated by simulation. The semiconductor layer 5 is composed of silicon. It is assumed that the inside of the groove 600 is filled with air. A wavelength of the light was decided as 905 nm, and the width of the groove 600 was decided as x. If the width x of the groove 600 is a length that is not less than at least the wavelength of the light, when the incident angle θ to the groove 600 becomes not less than a critical angle, it is possible to obtain the same effect as the effect when the width x is made an infinite value. However, if the width x is made too large, the photo detection region of the photo detector 1016 might be decreased. For the reason, the width x becomes not more than 1 mm at a maximum, for example.

### Modification of Eleventh Embodiment

FIG. 16A is a diagram showing a photo detector 1017, FIG. 16B is a GG′ sectional view of the photo detector 1017, and FIG. 16C is an SS′ sectional view of the photo detector 1017.

The same symbols are given to the same portions as in FIG. 14A, and the description thereof will be omitted.

In FIG. 16A and FIG. 16B, the photo detector 1017 is provided with the two-dimensional diffraction grating 821. In FIG. 16B, dotted lines show the positions of the depletion layers 71 inside the semiconductor layer 5.

In the photo detector 1017 of FIG. 18C, the incident light 400 is diffracted by the two-dimensional diffraction grating 821. The light 400 diffracted by the two-dimensional diffraction grating 821 spreads in all directions and reaches the groove 600. A part of the diffracted light 400 is totally reflected by the interface of the semiconductor layer 5 and the groove 600. But the remainder of the diffracted light 400 might pass from the semiconductor layer 5 to the groove 600.

On the other hand, in the photo detector 1016 of FIG. 14A, the whole of the light 400 is totally reflected by the interface of the semiconductor layer 5 and the groove 600. For the reason, the photo detector 1016 is easy to realize a higher detection efficiency than the photo detector 1017.

### Twelfth Embodiment

FIG. 17A is a diagram showing a photo detection device 1008, and FIG. 17B is a diagram of the photo detection device 1008 seen from an as plane or a yz plane.

In the photo detection device 1008, a plurality of the photo detectors 1008a are arranged. The photo detector 1008a is the photo detector 1016 or the photo detector 1017 which is described above. In the photo detection device 1008, the plurality of photo detectors 1008a are arranged, and thereby two-dimensional information can be obtained.

### (Manufacturing Method)

FIGS. 18A to 18F are diagrams for describing a manufacturing method of the photo detector 1003. Here, an example of a case to use Si as the semiconductor material will be shown.

To begin with, in FIG. 18A, an SOI (Silicon On Insulator) substrate is prepared. The SOI substrate has a structure in which a silicon substrate 91, a BOX (buried oxide layer) 52, an active layer (n type semiconductor layer) 40 are laminated in this order. The p⁻ type semiconductor layer 30 is formed on the n type semiconductor layer 40 by epitaxial growth.

Next, in FIG. 19B, impurities (boron, for example) are implanted into the p⁻ type semiconductor layer 30 so that a part of the region of the p⁻ type semiconductor layer 30 becomes the p⁺ type semiconductor layer 31. By this means, the p⁺ type semiconductor layer 31 composing a photo detection element is formed on a portion of the active layer 40 of the SOI substrate. In addition, a first mask not shown is formed on the p⁻ type semiconductor layer 30, and p type impurities are implanted into the p⁻ type semiconductor layer 30 using this first mask, to form the p⁺ type semiconductor layer 32 on the p⁻ type semiconductor layer 30 serving as a photo detection region.

In FIG. 18C, after the above-described first mask is removed, the one-dimensional diffraction grating 801 is formed in the x direction on the upper portion of the p⁻ type semiconductor layer 30, by dry etching or wet etching, for example.

In FIG. 18D, the insulating layer 50 is formed. The first electrode 10 is formed so as to cover the insulating layer 50 and a peripheral portion of the p⁺ type semiconductor layer 32. For example, metal such as Ag, Al, Au, Cu or an alloy thereof is used for the first electrode 10.

In FIG. 18E, a passivation layer 82 is formed so as to cover the one-dimensional diffraction grating 801 and the first electrode 10. A support substrate 92 is provided on the passivation layer 82. The support substrate 92 may be directly adhered to the passivation layer 82, or the support substrate 92 and the passivation layer 82 may be adhered to each other using an adhesive layer not shown. After the support substrate 92 is provided, the silicon substrate 91 is subjected to dry etching. In this dry etching, a reaction gas such as SF₆ can be used, for example. When a reaction gas having etch selectivity of the silicon substrate 91 and the BOX 52 is used in this dry etching, the BOX 52 can be used as an etching stop film. In addition, when the silicon substrate 91 is sufficiently thick, a polishing process such as back grinding and CMP (Chemical Mechanical Polishing), or wet etching may be used together. When wet etching is used, KOH or TMAH (Tetra-Methyl-Ammonium Hydroxide) can be used as etchant. When the silicon substrate 91 is etched by means of this, the BOX 52 is exposed.

In FIG. 18F, the exposed BOX 52 is removed by etching, and thereby the n type semiconductor layer 40 is exposed. As this etching, wet etching with hydrofluoric acid or the like can be used. Wet etching like this is used, and thereby etch selectivity of the BOX 52 and silicon can be sufficiently ensured, and the exposed BOX 52 can be selectively removed. After the n type semiconductor layer 40 is exposed, the reflective material 21 is formed on the n type semiconductor layer 40 so as to cover at least the photo detection region in which the p⁺ type semiconductor layers 31, 32 are provided.

### Thirteenth Embodiment

FIG. 19A is a diagram showing a measuring system, and FIGS. 19B, 19C are diagrams each showing a specific example of the measuring system.

The measuring system is composed of at least a photo detection device 1010 and a light source 3000.

In the measuring system, the light source 3000 emits a light 410 to a measuring object 500. The photo detection device 1019 detects a light 411 which has passed through the measuring object 500 or has reflected or diffused from the measuring object 500. The measuring system may be configured such that the light source 3000 and the photo detection device 1019 are respectively housed in separate chassis, for example, as shown in FIG. 19B. Or the light source 3000 and the photo detection device 1010 may be housed in the same chassis, as shown in FIG. 19C. Any of the photo detectors or the photo detection devices of the above-described embodiments is used as the photo detection device 1019, and thereby it is possible to realize a measuring system with high sensitivity, particularly in the near infra-red region.

### Fourteenth Embodiment

FIG. 20 is a diagram showing a LIDAR (Laser Imaging Detection and Ranging) device 5001.

The LIDAR device 5001 is provided with a light projecting unit and a light receiving unit.

The light projecting unit is composed of a light oscillator 304, a drive circuit 303, an optical system 305, a scan mirror 306, and a scan mirror controller 302. The light receiving unit is composed of a reference light detector 309, a photo detection device 310, a distance measuring circuit 308, and an image recognition system 307.

In the light projecting unit, the laser light oscillator 304 emits laser light. The drive circuit 303 drives the laser light oscillator 304. The optical system 305 extracts a part of the laser light as reference light, and irradiates an object 501 with the other laser light via the mirror 306. The scan mirror controller 302 controls the scan mirror 306, to irradiate an object 501 with the laser light.

In the light receiving unit, the reference light detection device 309 detects the reference light, extracted by the optical system 305. The photo detection device 310 receives the reflected light from the object 501. The distance measuring circuit 308 measures a distance to the object 501, based on the reference light detected by the reference light photo detection device 309 and the reflected light detected by the photo detection device 310. The image recognition system 307 recognizes the object 501 based on the result measured by the distance measuring circuit 308.

The LIDAR device 5001 is a distance image sensing system employing a light flight time ranging method (Time of Flight) which measures a time required for a laser light to reciprocate to a target, and converts the time into a distance. The LIDAR device 5001 is applied to an on-vehicle drive-assist system, remote sensing, and so on. If any of the photo detectors or the photo detection devices of the above-described embodiments is used as the photo detection device 310, the LIDAR device 5001 expresses good sensitivity, particularly in a near infra-red region. For this reason, it becomes possible to apply the LIDAR device 5001 to a light source in a human-invisible wavelength band. The LIDAR device 5001 can be used for obstacle detection for vehicle, for example.

While certain embodiments have been described, these embodiments have been presented by way of example only, and are not intended to limit the scope of the inventions. Indeed, the embodiments described herein may be embodied in a variety of other forms; furthermore, various emissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photo detector, comprising;
a semiconductor layer having a first light receiving surface and a second light receiving surface opposite to the first light receiving surface; and
a diffraction grating which is provided on the first light receiving surface side of the semiconductor layer and has convex portions, the convex portions being arranged in one direction at a predetermined cycle.

2. The photo detector according to claim 1, wherein:
the convex portion of the diffraction grating is stepwise.

3. The photo detector according to claim 1, wherein:
the convex portions of the diffraction grating are saw-tooth.

4. The photo detector according to claim 1, further comprising:
a substrate on the diffraction grating side that is a side opposite to the semiconductor layer side.

5. The photo detector according to claim 4, further comprising:
a reflective material on the second light receiving surface side of the semiconductor layer.

6. The photo detector according to claim 5, further comprising:
a spacer layer between the semiconductor layer and the reflective material.

7. The photo detector according to claim 1, further comprising:
a substrate provided on the second light receiving side of the semiconductor layer; and
a reflective material provided between the semiconductor layer and the substrate.

8. The photo detector according to claim 7, further comprising:
a spacer layer between the semiconductor layer and the reflective material.

9. The photo detector according to claim 5, further comprising:
a void portion in at least a part of periphery of the first light receiving surface of the semiconductor layer.

10. A photo detector, comprising:
a semiconductor layer having a first light receiving surface and a second light receiving surface opposite to the first light receiving surface;
a diffraction grating which is provided on the second light receiving surface side of the semiconductor layer and has convex portions, the convex portions being arranged in one direction at a predetermined cycle; and
a reflective material provided on the diffraction grating at a side opposite to the semiconductor layer.

11. The photo detector according to claim 10, further comprising:
a substrate provided on the first light receiving side of the semiconductor layer.

12. The photo detector according to claim 10, further comprising:
a substrate provided on the reflective material at a side opposite to the diffraction grating side.

13. The photo detector according to claim 1, wherein:
the semiconductor layer includes a laminated structure which includes an n⁺ type semiconductor layer, an n⁻ type semiconductor layer, an n⁺ type semiconductor layer, and a p type .semiconductor layer in this order.

14. The photo detector according to claim 1, wherein:
the semiconductor layer includes a laminated structure which includes a p⁺ type semiconductor layer, a p⁻ type semiconductor layer, a p⁺ type semiconductor layer, and an n type semiconductor layer in this order.

15. The photo detector according to claim 1, wherein:
a wavelength of a light incident on the first light receiving surface or the second light receiving surface is not less than 750 nm and not more than 1000 nm.

16. The photo detector according to claim 1, wherein:
the semiconductor layer includes Si.

17. A photo detection device, comprising:
a plurality of the arranged photo detectors according to claim 1.

18. The photo detection device according to claim 17, further comprising:
a reflection wall provided between the relevant photo detectors of the plurality of arranged photo detectors.

18. A LIDAR device, comprising:
a light source to irradiate an object with light;
the photo detection device of claim 17 which detects the light reflected by the object; and
a measuring unit to measure a distance between the object and the photo detection device.
